(19) United States
(12) Patent Application Publication
(10) Pub. No.: US 2026/0022492 A1
(43) Pub. Date: Jan. 22, 2026

(54) TEMPERATURE AND FILM ADJUSTMENTS FOR PROCESS CHAMBERS, AND RELATED SYSTEMS AND METHODS

(71) Applicant: Applied Materials, Inc., Santa Clara, CA (US)

(72) Inventors: Khokan C. PAUL, Cupertino, CA (US); Sathya Shrinivas CHARY, San Francisco, CA (US); Akhil MEHROTRA, Sunnyvale, CA (US); Lori D. WASHINGTON, San Jose, CA (US)

(21) Appl. No.: 18/779,927

(22) Filed: Jul. 22, 2024

(51) Int. Cl. C30B 25/16; C23C 16/458; C23C 16/46; C23C 16/52; H01L 21/66; H01L 21/67

(52) U.S. Cl. CPC C30B 25/16; C23C 16/4583; C23C 16/46; C23C 16/52; H01L 21/67248; H01L 22/12

(57) ABSTRACT

Embodiments of the present disclosure relate to temperature and film adjustments for process chambers, and related systems and methods. In one or more embodiments, a substrate processing system includes a chamber body at least partially defining a processing volume, and a substrate support disposed in the processing volume and configured to support a substrate. The substrate processing system includes one or more gas inlets operable to provide a processing gas that flows horizontally across the processing volume and over the substrate support, and one or more heat sources operable to heat the substrate. The substrate processing system includes a laser source operable to direct energy to the substrate to provide supplemental heating, a thickness sensor operable to measure a film thickness on the substrate, and a controller operable to control the laser source based on the measured film thickness.

### BACKGROUND

Embodiments of the present disclosure relate to temperature and film adjustments for process chambers, and related systems and methods.

### DESCRIPTION OF THE RELATED ART

Semiconductor substrates are processed for a wide variety of applications, including the fabrication of integrated devices and microdevices. Precise control over a heating source allows a substrate to be heated within tolerances. The temperature of the substrate can affect the uniformity of the material deposited on the substrate. For example, film thickness non-uniformities can occur across a substrate in a non-uniform manner. It can be difficult to measure and/or adjust process parameters, such as temperature and/or film growth, in a real-time manner. Adjustments can also involve opening of the process chamber and machine down time.

Therefore, a need exists for improved process chambers, systems, and methods.

### SUMMARY

Embodiments of the present disclosure relate to temperature and film adjustments for process chambers, and related systems and methods.

In one or more embodiments, a substrate processing system includes a chamber body at least partially defining a processing volume, and a substrate support disposed in the processing volume and configured to support a substrate. The substrate processing system includes one or more gas inlets operable to provide a processing gas that flows horizontally across the processing volume and over the substrate support, and one or more heat sources operable to heat the substrate. The substrate processing system includes a laser source operable to direct energy to the substrate to provide supplemental heating, a thickness sensor operable to measure a film thickness on the substrate, and a controller operable to control the laser source based on the measured film thickness.

In one or more embodiments, a method of monitoring substrate processing includes measuring a film thickness in a processing volume of a process chamber. The method includes determining if a film thickness difference of a location in the processing volume exceeds a threshold, and adjusting a laser source if the film thickness difference exceeds the threshold.

In one or more embodiments, a substrate processing system includes a chamber body at least partially defining a processing volume, a substrate support disposed in the processing volume, and a first temperature sensor operable to measure a first temperature at a first radial location in the processing volume. The substrate processing system includes a second temperature sensor operable to measure a second temperature at a second radial location in the processing volume. The second radial location is outwardly of the first radial location. The substrate processing system includes a heat source operable to direct energy into the processing volume, and a controller. The controller is configured to determine if a temperature difference between the first temperature and the second temperature exceeds a threshold, and adjust the heat source if the temperature difference exceeds the threshold.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a processing system, according to one or more embodiments.

FIG. 2 is a partial schematic cross-sectional view of an in-situ reflectometry system (ISR) that can be used as at least part of the measurement assembly, according to one or more embodiments.

FIG. 3 is a schematic partial top plan view of the process chamber shown in FIG. 1, according to one or more embodiments.

FIG. 4 is a schematic graphical view of a film thickness profile of a processed substrate.

FIG. 5 is a schematic partial side view of the process chamber shown in FIG. 3, according to one or more embodiments.

FIG. 6 is a schematic partial side view of the process chamber shown in FIG. 3, according to one or more embodiments.

FIG. 7 is a schematic plan view of an adjustment method, according to one or more embodiments.

FIG. 8 is a schematic plan view of an adjustment method, according to one or more embodiments.

FIG. 9 is a schematic graphical view of the edge measurements of block plotted in a signal profile, according to one or more embodiments.

FIG. 10 is a schematic graphical view of the averaged measurements of block plotted in a signal profile, according to one or more embodiments.

FIG. 11 is a schematic flow diagram view of a method of monitoring substrate processing, according to one or more embodiments.

FIG. 12 is a schematic partial top plan view of the process chamber shown in FIG. 1, according to one or more embodiments.

FIG. 13 is a schematic view of a data table, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to temperature and film adjustments for process chambers, and related systems and methods.

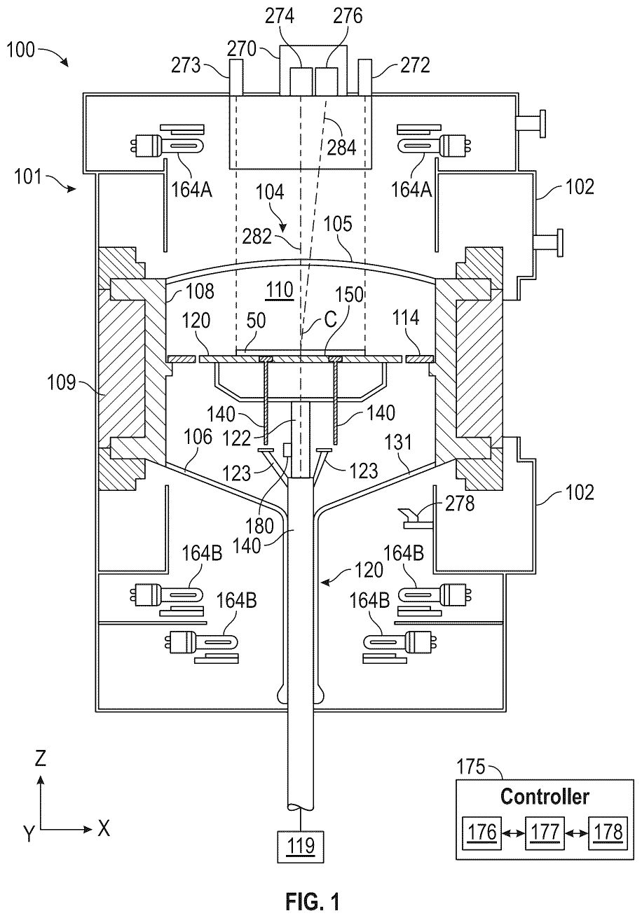

FIG. 1 is a schematic cross-sectional view of a processing system 100, according to one or more embodiments. The processing system 100 includes a process chamber 101 and a controller 175. The processing system 100 can be configured to conduct epitaxial deposition processes in the process chamber 101.

The process chamber 101 includes a housing structure 102 made of a process resistant material, such as aluminum or stainless steel, for example 316L stainless steel. The housing structure 102 can be at least part of a chamber body. The housing structure 102 encloses various functioning elements of the process chamber 101, such as a quartz chamber 104, which includes an upper quartz window 105 and a lower quartz window 131. The quartz chamber 104 encloses an interior volume 110 (also referred to as a processing volume). One or more liners 108, 109 can protect the housing structure 102 from reactive chemistry and/or can insulate the quartz chamber 104 from the housing structure 102. The process chamber 101 includes a substrate support 120. A substrate 50 can be positioned on the substrate support 120 during processing, such as during depositions.

The process chamber 101 can further include upper heat sources 164A and lower heat sources 164B for heating of the substrate 50 and/or the interior volume 110. The heat sources 164A, 164B can be radiant heat sources such as lamps, for example halogen lamps and/or infrared (IR) lamps. In one or more embodiments, the heat sources 164A, 164B are operable to emit IR light and/or ultraviolet light. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 120 is coupled to an actuator 119, an outer shaft 121, and inner shaft 122. The actuator 119 is configured to vertically move the inner shaft 122 relative to the outer shaft 121. The actuator 119 is further configured to rotate the inner shaft 122 while the outer shaft 121 remains stationary. The inner shaft 122 is configured to rotate about a central axis C extending in the vertical direction through the center of the inner shaft 122.

In one or more embodiments, the substrate support 120 is formed of an opaque material (such as white quartz, grey quartz, quartz with impregnated particles (such as SiC particles or silicon particles), black quartz, silicon carbide (SiC), and/or graphite coated with SiC)). The process chamber 101 can include a preheat ring 114 that can be positioned around the substrate support 120, and a plurality of lift pins 140. The lift pins 140 can be formed of quartz (such as transparent quartz). The lift pins 140 can be positioned and configured to lift a substrate 50 above the substrate support 120 to allow the substrate 50 to be transferred to and from the interior volume 110 of the process chamber 101. Lift pin pads 123 can be attached to the outer shaft 121. More or less lift pin pads (e.g., two lift pin pads) can be used. In one or more embodiments, the lift pin pads 123 are formed of quartz (such as transparent quartz). The lift pin pads 123 can be positioned 120 degrees (or another angle) apart from each other relative to the central axis C that extends through a center of the outer shaft 121.

The actuator 119 can lower the inner shaft 122 causing the lift pins 140 to contact the lift pin pads 123 and push the substrate 50 above the substrate support 120. In one or more embodiments, one or more of the lift pin pads 123 can include a sensor (e.g., a proximity sensor) connected to the controller 175 to detect when one or more of the lift pins 140 overlies one or more of the lift pin pads 123. The controller 175 can use the feedback from the sensor to stop the rotation of the substrate support 120 by the actuator 119. This can enable the controller to align the first plurality of lift pins 140A to overlie the lift pin pads 123 for lifting the substrate 50.

In one or more embodiments, the process chamber 101 can include an encoder 180. In one or more embodiments, the encoder can be attached to an outside of the inner shaft 122, such as near a bottom of the inner shaft 122. The encoder 180 can be used to control the angular amount (e.g., 60 degrees, 90 degrees, 180 degrees, etc.) from a home position that the substrate support 120 has rotated. Determining and controlling this angular rotation of the inner shaft 122 enables the substrate support 120 to be rotated to any angle from a home position, which provides the capability for the substrate support 120 and substrate 50 to be rotated to angular positions and/or using angular speeds.

The processing system 100 also includes the controller 175 for controlling processes performed by the processing system 100. The controller 175 can be any type of controller used in an industrial setting, such as a programmable logic controller (PLC). The controller 175 includes a processor 177, a memory 176, and input/output (I/O) circuits 178. The controller 175 can include one or more of the following components, such as one or more power supplies, clocks, communication components (e.g., network interface card), and user interfaces typically found in controllers for semiconductor equipment.

The memory 176 can include a non-transitory memory (e.g., a non-transitory computer readable medium). The non-transitory memory can be used to store the programs and settings described below. The memory 176 can include one or more readily available types of memory, such as read only memory (ROM) (e.g., electrically erasable programmable read-only memory (EEPROM)), flash memory (e.g., flash drive), floppy disk, hard disk, random access memory (RAM) (e.g., non-volatile random access memory (NVRAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), or any other form of digital storage, local or remote.

The processor 177 is configured to execute various programs stored in the memory 176, such as epitaxial deposition processes and processes for transferring substrates and susceptors into and out of the interior volume 110. During execution of these programs, the controller 175 can communicate to I/O devices through the I/O circuits 178. For example, during execution of these programs and communication through the I/O circuits 178, the controller 175 can control outputs, such as the rotational position of substrate support 120 relative to the lift pin pads 123 and the vertical position of the substrate support 120 through use of the actuator 119. The memory 176 can further include various operational settings used to control the processing system 100.

The controller 175 is configured to conduct any of the operations described herein. In one or more embodiments, the instructions stored on the memory 176, when executed, cause one or more of operations of methods described herein (such as method 800 described below) to be conducted in relation to the processing chamber 101. The various operations described herein (such as the operations of the method 800) can be conducted automatically using the controller 175, or can be conducted automatically or manually with certain operations conducted by a user.

The instructions stored in the memory 176 of the controller 175 can include one or more machine learning/artificial intelligence algorithms that can be executed in addition to the operations described herein. As an example, a machine learning/artificial intelligence algorithm executed by the controller 175 can generate, prioritize, accept, and/or reject profiles and/or data (such as measurements, averaged measurements, calibrated measurements, thresholds, and/or adjusted parameters) used in relation to the methods described herein (such as the method 800). The machine learning/artificial intelligence algorithm can account for previous operational runs to monitor and update the reference profiles and/or data. For example, the machine learning/artificial intelligence algorithm can select and/or adjust the threshold(s) and/or the moving average used to calculate averaged measurements. The machine learning/artificial intelligence algorithm can optimize the adjusted process parameter(s) of adjusted process recipes. The one or more machine learning/artificial intelligence algorithms can use, for example, a regression model (such as a linear regression model) or a clustering technique to estimate optimized data. The algorithm(s) can be unsupervised or supervised. In one or more embodiments, the controller 175 automatically conducts the operations described herein without the use of one or more machine learning/artificial intelligence algorithms. In one or more embodiments, the controller 175 compares measurements to data in a look-up table and/or a library to make determinations. The controller 175 can store measurements as data in the look-up table and/or the library.

The processing system 100 includes a measurement assembly 270 including a sensor 276. The sensor 276 is a thickness sensor operable to measure a film thickness of film grown on the substrate 50 in the processing volume 110. In one or more embodiments, the processing system 100 includes a second sensor 272 and/or a third sensor 273. In one or more embodiments, the sensor 276 includes a reflectometer, the second sensor 272 includes a temperature sensor, and/or a third sensor 273 includes a temperature sensor. The controller 175 can control the measurement assembly 270 and/or the sensor(s) 272, 273, and adjust a process recipe of processing conducted using the processing chamber 101. In one or more embodiments, the sensors 272, 273 respectively include temperature sensor, such as a pyrometer that includes a silicon sensor. In one or more embodiments, the sensors 272, 273 respectively include an optical sensor, such as an optical pyrometer. The measurement assembly 270 includes an energy source 274 (e.g., a light source) and the sensor 276. The sensors 272, 273, the energy source 274, and the sensor 276 are disposed above the substrate 50. The energy source 274 and the sensor 276 can be part of a thickness sensor. A lower temperature sensor 278 is disposed below the substrate 50. The energy source 274 is positioned to emit an energy toward a surface (such as a top surface 150 of the substrate 50), and the sensor 276 is disposed adjacent to the energy source 274 and positioned to receive the emitted energy that is reflected off of the substrate 50.

The energy source 274 can emit, for example, infrared light and/or ultraviolet light. In one or more embodiments, the energy source 274 is a laser light source with a controlled intensity and wavelength range. In one or more embodiments, a broadband light source is used. The energy source 274 may be a diode laser or an optical cable. When the energy source 274 is an optical cable, the optical cable is connected to an independent energy source (e.g., light source), which may be disposed near the process chamber 101. The energy source 274 may be a bundle of lasers or optical cables, such that a plurality of beams (e.g., light beams) are focused into a beam 282 (e.g., a light beam). In one or more embodiments, the energy source 274 can emit radiation at a varying wavelength range. The use of a varying wavelength range eliminates noise that may be caused by the use of a wider wavelength spectrum and allows for an increase in the strength of emission of the narrower range from the energy source 274 to increase the signal strength received by the sensor 276. In one or more embodiments, one or more of the heat sources 164A are used as the energy source 274. In one or more embodiments, the energy source 274 may be classified as a radiation source, such as a thermal radiation source or a broadband radiation source. The radiation source may be a laser diode or an optical assembly. The optical assembly may include a laser, a lamp, and/or a bulb, and/or a plurality of lenses, mirrors, or a combination of lenses and mirrors.

The sensor 276 measures the intensity of different wavelengths of energy (e.g., light) within a second beam 284 (e.g., second light beam), which is reflected off the substrate 50. The sensor 276 can be configured to measure an intensity of the second beam 284. The sensor 276 may include several optical components disposed therein in order to separate and measure the second beam 284. In one or more embodiments, the sensor 276 is a scanning band edge detector. An optional filter may be placed between the sensor 276 and the substrate support 120 and configured to filter out radiation emitted by the heat sources 164A, 164B.

As discussed below, a thickness sensor can be used to measure the same locations as each of the second sensor 272 and/or the third sensor 273. As discussed below a temperature sensor (such as a pyrometer) can be used to measure the same location as the thickness sensor 276.

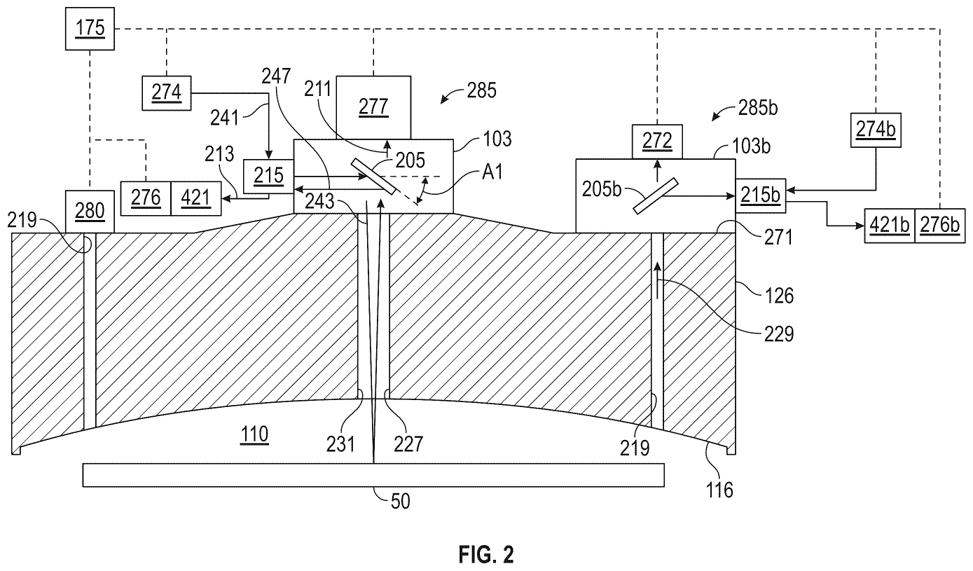

FIG. 2 is a partial schematic cross-sectional view of an in-situ reflectometry system (ISR) 285 that can be used as at least part of the measurement assembly 270, according to one or more embodiments. The present disclosure contemplates that other configurations may be used for the measurement assembly 270, for example other than reflectometers. The ISR System 285 includes the energy source 274, a collimator 215, the sensor 276, the second sensor 272, and a dichroic mirror 205 coupled to or disposed above the chamber lid 271. The ISR System 285 facilitates measurement of one or more properties of the substrate 50 (and/or a film disposed thereon). Example properties include temperature, film growth rate, thickness of a film, thin film optical properties and/or in-film concentration (e.g., Ge concentration and/or a dopant concentration, such as of phosphorus). The collimator 215 can be spaced from the dichroic mirror 205 by a distance within a range of 200 nm to 800 nm. Other distances are contemplated.

The energy source 274 is configured to generate energy 241 (e.g., radiation, such as light). For example, the energy source 274 could be a flash lamp, capable of producing full spectrum or partial spectrum light. In one or more embodiments, the spectrum of light generated has a wavelength between about 200 nm to about 4 micrometers, such as 200 nm to about 800 nm and/or 3 micrometers to 4 micrometers. Full spectrum light can allow for a wide range of light signals for analysis, however in one or more embodiments a light source may be limited to a specific wavelength of light or specific range of light wavelengths to accomplish the analysis. The energy source 274 may be controlled by the controller 175. The energy source 274 is in optical communication with the collimator 215, and directs energy 241 to the collimator 215 upon instruction of the controller 175. Optical communication includes connection by a fiber optic cable, and other modes of light transmission are contemplated. The travel path of the energy from the energy source 274 may be referred to as a propagation path. The collimated energy 243 (e.g., radiation, such as light, for example a light beam) leaves the collimator 215, and travels through a passage 231. In one or more embodiments, the passage 231 includes a light pipe. The passage 231 can be a made of any material capable of transmitting light of predetermined wavelengths, for example, sapphire, gold, gold-coated stainless steel, and/or polished aluminum. The passage 231 directs the collimated energy 243 to the surface of the substrate 50 (or a film thereon) to facilitate measurement of one or more properties of the substrate 50 (or a thin film thereon).

The collimated energy 243 is reflected off the target measurement surface, such as the substrate 50, and is reflected back as reflected energy 227. The reflected energy 227 can carry radiation information that relates to the temperature of the substrate surface of the surface 50. The reflected energy 227 travels back through the passage 231 such that the information can be measured. The reflected energy 227 leaves the passage 231 and travels to the dichroic mirror 205 aligned with the passage 231 along the travel path of the reflected energy 227. In one or more embodiments, the dichroic mirror 205 includes a transparent material with a dielectric coating. The dielectric coating may include, but is not limited to, magnesium fluoride, tantalum pentoxide, and/or titanium dioxide. The ISR 285 includes a temperature sensor 277. In one or more embodiments, the temperature sensor 277 includes a pyrometer that includes a silicon sensor. In one or more embodiments, the temperature sensor 277 includes an optical sensor, such as an optical pyrometer. The passage 231 can reduce radiation noise from the heat sources 164A, 164B for the sensor 276 and the temperature sensor 277.

The dichroic mirror 205 reflects certain wavelengths of energy (e.g., light) away to the collimator 215, but allows other specifically selected wavelengths to pass through to the temperature sensor 277. A wavelength range directed to the sensor 276 through the collimator 215 may be between about, 100 nm and about 1000 nm, such as within a range of 200 nm and 800 nm, such as within a range of 200 nm and 400 nm, and such as within a range of 400 nm and 800 nm. Other wavelengths are contemplated. The dichroic mirror 205 facilitates multiple light based sensors to be used by directing light of a first desired range of to one sensor (such as the thickness sensor 276) with the remaining light wavelengths being sent to at least another sensor (such as the temperature sensor 277). Thus, use of optical spectrometer(s) and/or the ISR system 285 facilitates a compact measurement system, allowing more sensors to be included in a smaller footprint. The dichroic mirror 205 is arranged, or oriented, at an angle of incidence A1 between about, 30° and about 60°, such as within a range of 35° and 55°, with a plane near orthogonal to a longitudinal axis of the passage 231. However, other angles of incidence are contemplated.

As shown in FIG. 2, light transmitted through the dichroic mirror 205 is transmitted to the temperature sensor 277 along an energy path 211 (e.g., a light path). In one or more embodiments, light wavelengths between about 1.0 μm and about 6.0 μm, such as between about 3.0 μm and about 4.0 μm, travel along the energy path 211 to the temperature sensor 277. As noted above, properties of the dichroic mirror 205 are selected to transmit or reflect light in specified wavelength ranges. Energy 247 (e.g., light) reflected by the dichroic mirror 205 is collimated by the collimator 215. The collimated energy 213 is directed to the thickness sensor 276. In one or more embodiments, the sensor 276 includes a spectrometer such as an optical spectrometer, such as a spectrograph configured to measure wavelength-resolved intensity. The thickness sensor 276 can include a grating, an optical lens, a charge-coupled device (CCD) array, a filter 421 and/or a linear-array photodiode detector. The thickness filter 421 can be a short pass filter to limit the noise from a heat source (such as the heat sources 164A, 164B), or a dielectric filter. A dielectric filter includes any thin film based filters than can reduce or prevent specific wavelength of light from passing therethrough. While the filter 421 is described as part of the sensor 276, it is contemplated that the filter can be located in other locations. For example, the filter 421 can be part of the dichroic mirror 205. The filter 421 is configured to allow light of a specified wavelength to pass therethrough, while reducing or preventing passing or other wavelengths. In one or more embodiments, the filter 421 allows light of wavelengths below 550 nm to pass therethrough (while filtering other wavelengths) to mitigate light signal noise from heat sources of the process chamber, thus improving measurement accuracy. It is contemplated that the filter 421 can be placed in any light path that includes the light reflected off the substrate 50 (e.g., reflected energy 227 to the sensor 276, reflected energy 247 from dichroic mirror 205, energy along energy path 211, and/or collimated energy 243). In one or more embodiments, the filter 421 is an integral component of the sensor 276. In one or more embodiments, the filter 421 is a standalone component from the sensor 276. In one or more embodiments, the filter 421 is not included in the path. It is to be noted that while one or more embodiments described herein may include a filter 421 and/or a dichroic mirror 205, both the filter 421 and the mirror 205 are optional and may be excluded from any embodiment or implementation described herein.

In one or more embodiments, a second ISR 285b includes the second sensor 272 (e.g., a second temperature sensor 272) similar to the additional sensor 277, an energy source 274b (similar to the energy source 274), a collimator 215b (similar to the collimator 215), a housing 103b (similar to a housing 103), a mirror 205b (similar to the dichroic mirror 205), a filter 421b (similar to the filter 421), and a thickness sensor 276b (similar to the thickness sensor 276).

For the second ISR 285b, the reflected signal travels back to the dichroic mirror 205b and is split into multiple paths (e.g., propagation sub-paths). A first propagation sub-path directs transmitted light to the second sensor 272, while a second propagation sub-path directs reflected light to the collimator 215b and then to the thickness sensor 276b. The light intensity collected by the thickness sensor 276 can be analyzed for true reflectance, which is compared with models, for example (Fresnel equations) using nonlinear fitting equations or other empirically derived equations to determine an emissivity (e.g., using a reflectance) of the substrate 50. The temperature sensor 272 can measure a temperature of the substrate 50. The thickness sensor 276b and the temperature sensor 272 are respectively configured to measure a growth rate and/or a temperature of an outer region of the substrate 50, an outer region of the substrate support 120, and/or the pre-heat ring 114.

In one or more embodiments, models are empirically derived by obtaining absorption/reflectance data for light at predetermined wavelengths for various materials of the substrate 50 and/or other processed substrates. The data may be collected at conditions that approximate those of a predetermined recipe for processing future substrates, such as a process recipe at which the model will be used. The data is then fit to an equation, such as a non-linear equation. Light received by the sensor 276 is analyzed for intensity (e.g., true reflectance of light reflected from the measured substrate 50) and fit to the empirically derived equation to determine the emissivity of the substrate 50. Stated otherwise, the amount of light reflected from the top surface 150 of the substrate 50 changes depending upon the material of film on the substrate 50 and/or a thickness of the material of the film. The amount of light can be compared to known data to determine the emissivity and/or a shift in emissivity. This data and/or equations may also take into account other optical properties, such as refractive index and/or extinction coefficient, to facilitate measurement accuracy. The substrate support 120 can rotate the substrate 50 such that measurements are taken at a plurality of azimuthal locations on the substrate 50 and/or the substrate support 120. The present disclosure contemplates that a plurality of emissivity measurements (for the same substrate or across a variety of substrates) can be averaged for an adjusted emissivity (e.g., a correction value) to be applied to emissivity measurements.

The processing chamber 101 includes a heat source 280 operable to direct energy into the processing volume 110. In one or more embodiments, the heat source 280 is a laser source (crystal lasers, laser diodes and arrays, and VCSEL's) operable to emit laser light. In one or more embodiments, the heat source 280 includes an electromagnetic radiant source, such as a high intensity electromagnetic radiant source, a pulsing electromagnetic radiant source or a continuous wave (CW) electromagnetic radiant source. Other heat sources, such as a high intensity light-emitting diode, are contemplated for the heat source 280. The heat source 280 can be used to adjust (e.g., correct) for deposition non-uniformities. For example, the heat source 280 can be used to adjust cold spots along the substrate 50. The second ISR 285b and the heat source 280 respectively are configured to be in line (e.g., vertically and/or optically aligned) with an outer passage 219. The outer passages 219 extend between a bottom surface and an upper surface of the chamber lid 271. The outer passages 219 may be sealed at upper and lower ends thereof by a material capable of transmitting energy 229 (e.g., light), such as quartz or sapphire. In one or more embodiments, each outer passage 219 includes a fiber optic cable disposed thereon. The heat source 280 and the second heat source 281 can be movable to direct (e.g., scan) energy across an entirety of a radius of the substrate 50 for correcting any location of uniformity along the radius of the substrate 50. The heat sources 164A, 164B can be part of primary heating assembly that heats one or more zones of the substrate 50. Supplemental heat sources herein (such as the heat source 280 and/or the second heat source 281) can be part of an auxiliary heating assembly that can be used for more narrow temperature control based on localized temperature and thickness difference thresholds and the correlation thereof to maintain thickness uniformity at locations along the substrate 50. In one or more embodiments, the heat source 280 and/or the second heat source 281 includes an adjustable-power laser source. The supplemental heat sources can provide supplemental heating, in addition to the primary heating of the heat sources 164A, 164B.

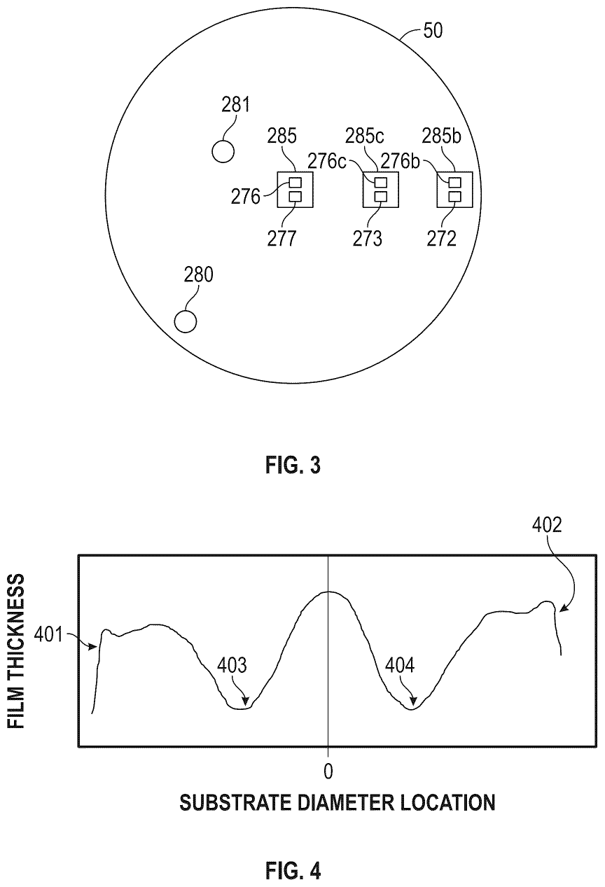

FIG. 3 is a schematic partial top plan view of the process chamber 101 shown in FIG. 1, according to one or more embodiments.

The process chamber 101 includes the ISR 285, the second ISR 285b disposed radially outwardly of the ISR 285. The process chamber 101 includes a third ISR 285c disposed radially between the ISR 285 and the second ISR 285b. The third ISR 285c is similar to the ISR 285. For example, the third ISR 285c includes a third thickness sensor 276c and the third sensor 273 (e.g., a third temperature sensor). The process chamber 101 includes a second heat source 281 that can be similar to the heat source 280. The second heat source 281 is disposed radially between the heat source 280 and the ISR 285. The second heat source 281 can be radially aligned with the third ISR 285c and/or the heat source 280 can be radially aligned with the second ISR 285b. In one or more embodiments, the heat source 280 is used to correct a center-to-edge non-uniformity and the second heat source 281 is used to correct a localized non-uniformity.

The thickness sensor 276 measures the film thickness at a first location (e.g., a first radial location, such as a center location) in the processing volume 110, and the temperature sensor 277 measures a temperature at the first location. The second thickness sensor 276b measures the second film thickness at a second location (e.g., a second radial location, such as an edge location) in the processing volume 110, and the second temperature sensor 272 measures a second temperature at the second location. The third thickness sensor 276c measures the third film thickness at a third location (e.g., a third radial location, such as an intermediate location) in the processing volume 110, and the third temperature sensor 273 measures a third temperature at the third location.

FIG. 4 is a schematic graphical view of a film thickness profile of a processed substrate. The film thickness profile can be measured, for example, along a linear line that extends through a center of the substrate 50 shown in FIG. 3, and extends across a diameter of the substrate 50 shown in FIG. 3. The film thickness profile includes locations 401-404 of non-uniformity where the film thickness drops off. The heat source 280 can be used to correct radially outward locations 401, 402 of non-uniformity, and/or the second heat source 281 can be used to correct radially inward locations 403, 404 of non-uniformity.

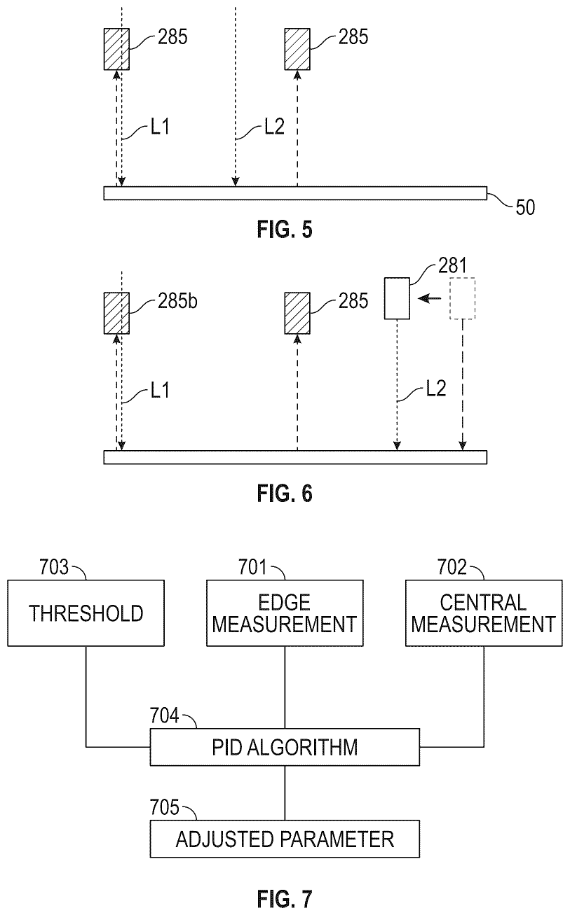

FIG. 5 is a schematic partial side view of the process chamber 101 shown in FIG. 3, according to one or more embodiments.

The ISR 285 measures a temperature and/or a film thickness of a location corresponding to a central region of the substrate 50, and the second ISR 285b measures a second temperature and/or a second film thickness of a second location corresponding to an outer region (such as an edge region) of the substrate 50. Light L1 from the light source 280 is directed to the outer region of the substrate 50. The light source 280 can be controlled (e.g., using the controller 175) with a feedback control based on measurements of the second ISR 285b. For example, when the measurements of the second ISR 285b at a location indicate a value falling below a threshold, the light source 280 can be moved and/or adjusted in power to irradiate the location of non-uniformity. As another example, when the measurements of the second ISR 285b and the ISR 285 indicate a difference (e.g., between a center and an edge of the substrate 50) fall below a threshold, the light source 280 can be moved and/or adjusted in power to irradiate the location of non-uniformity. The movement can adjust a target location of the light source 280. The adjustment in power can increase the power, decrease the power, and/or turn on the power. Light L2 from the second light source 281 is directed to an inner region of the substrate 50. The second light source 281 can be controlled with feedback control using the controller 175, and/or the second light source 281 can be controlled manually (such as by using input of a user).

FIG. 6 is a schematic partial side view of the process chamber 101 shown in FIG. 3, according to one or more embodiments.

As shown in FIG. 6, the second heat source 281 is movable between a radially outward position and a radially inward position. As shown, the second heat source 281 is moved in a lateral manner. The second heat source 281 can pivot to scan across the substrate 50. The second heat source 281 can rotate to adjust a field of view of the second heat source 281. The present disclosure contemplates that the sensors described herein (such as the ISR 285 and/or the second ISR 285b) can be movable in the same manner (e.g., laterally and/or pivotably to scan across a variety of locations in the processing volume 110) as described for the heat sources 280, 281.

FIG. 7 is a schematic plan view of an adjustment method, according to one or more embodiments. FIG. 7 can represent a calculation data flow for a calculation and adjustment controlled by the controller 175. As an example, FIG. 7 can represent the feedback control for the second heat source 285b. Block 701 is an edge measurement measured, for example, by the second ISR 285b, and block 702 is a central measurement measured, for example, by the ISR 285. Blocks 701, 702 can be, for example, temperature and/or film thickness. Block 703 is a threshold for a measurement difference. The threshold can be selected by a user and/or can be selected by using prior processing runs to correspond to a known thickness difference. The threshold can be selected from a look-up table that includes temperature differences corresponded to thickness differences. Blocks 701-703 are input into block 704, which is an algorithm. The algorithm can be, for example, a proportional-integral-derivative (PID) algorithm. The data of blocks 701, 702 can be continuously measured, and a sample time can be set for the algorithm of block 704. Block 705 calculates an adjusted parameter by comparing the data of blocks 701, 702 with the data of block 703. The adjusted parameter can be for example, a power, an orientation, and/or a position of the second ISR 285b. In one or more embodiments, the measurement difference is determined across a time interval and the adjusted parameter is generate for any time in the time interval where the measurement difference exceeds the threshold.

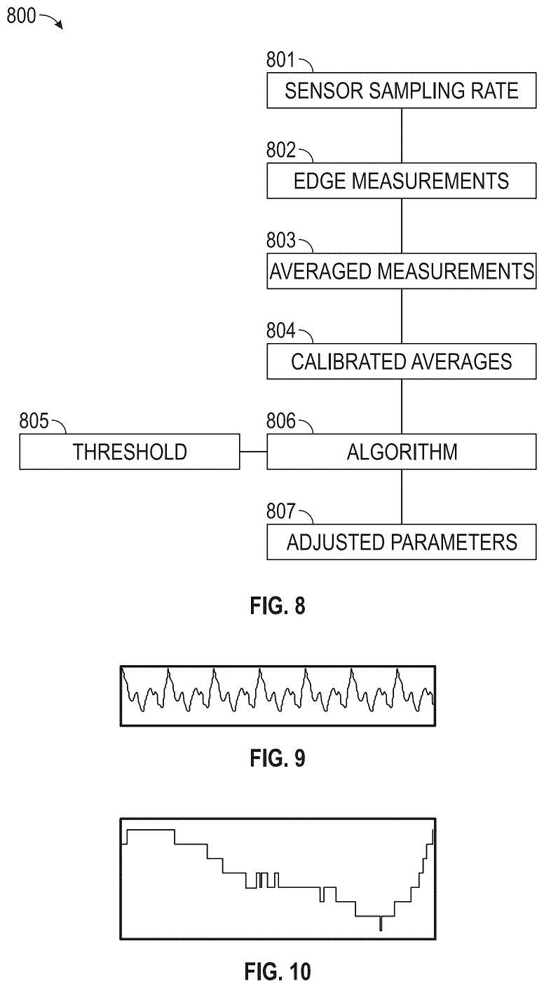

FIG. 8 is a schematic plan view of an adjustment method, according to one or more embodiments. FIG. 8 can represent a calculation data flow for a calculation and adjustment controlled by the controller 175. As an example, FIG. 8 can represent the feedback control for the second heat source 285b. Block 801 is a sampling rate for the second temperature sensor 272 and/or the thickness sensor 276b of the second ISR 285b.

Block 802 is a set of edge measurements measured, for example, by the second ISR 285b. The edge measurements can be, for example, temperature and/or film thickness. Block 803 is a set of averaged measurements that are calculated using a moving average across a time interval over which the edge measurements are measured. The time intervals can be, for example, sixty-second intervals, thirty-second intervals, twenty-second intervals, fifteen-second intervals, ten-second intervals, five-second intervals, one-second intervals, half-second intervals, or quarter-second intervals. The time intervals can be times that correspond to rotation segments, such as the time needed for a full substrate rotation, a half substrate rotation, or a quarter substrate rotation. Other time intervals are contemplated. Block 804 is a set of calibrated averages that are made by comparing the averaged measurements to calibration data (such as data in a look-up table) and adjusting (e.g., correcting) the averaged measurements.

Block 805 is a threshold for a measurement difference. Blocks 804, 805 are input into block 806, which is an algorithm. The algorithm can be, for example, a PID algorithm. The data of blocks 802-804 can be continuously measured, and a sample time can be set for the algorithm of block 806. Block 807 calculates a set of adjusted parameters by comparing the data of block 804 with the data of block 805. The adjusted parameters can be for example, a power, an orientation, and/or a position of the second ISR 285b. The adjusted parameters can be applied for locations of the substrate 50 that correspond to the time intervals of the calibrated averages that fall below the threshold.

The present disclosure contemplates that the method of FIG. 7 can be conducted to adjust the second heat source 281 in relation to a first radial location and the method of FIG. 8 can be conducted to adjust the heat source 280 in relation to a second radial location that is outwardly of the first radial location.

FIG. 9 is a schematic graphical view of the edge measurements of block 802 plotted in a signal profile, according to one or more embodiments.

FIG. 10 is a schematic graphical view of the averaged measurements of block 803 plotted in a signal profile, according to one or more embodiments.

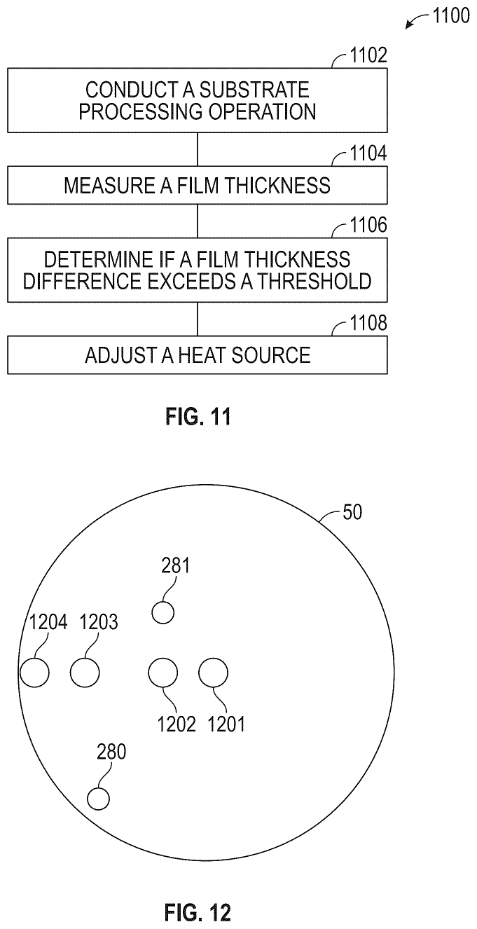

FIG. 11 is a schematic flow diagram view of a method 1100 of monitoring substrate processing, according to one or more embodiments.

Optional operation 1102 includes conducting a substrate processing operation in a process chamber. The substrate processing operation may include a deposition process on a substrate and/or an etching process on the substrate. The substrate processing operation may further include heating the substrate, introducing at least one process gas, introducing a purge gas, and evacuating the process and purge gases. A single substrate or a plurality of substrates can be processed during the substrate processing operation.

Operation 1104 includes measuring a film thickness and/or a temperature in a processing volume of the process chamber. In one or more embodiments, the film thickness and/or the temperature are measured on the substrate. In one or more embodiments, the film thickness and/or the temperature are determined across one or more of a plurality of azimuthal locations or a time interval. In one or more embodiments, the film thickness and/or the temperature are determined across one or more of a plurality of radial locations (such as from a center to the substrate to the edge of the substrate).

Operation 1106 includes determining if a film thickness difference and/or a temperature difference of a location in the processing volume exceeds a threshold. In one or more embodiments, the threshold is an average of the film thickness or the temperature measured at a substrate location (such as a radial location) across a rotation of the substrate. In one or more embodiments, the threshold is an average of the film thickness or the temperature measured across a radial dimension of the substrate. The radial dimension can extend across an outer diameter of a processed substrate and through a center of the substrate. In one or more embodiments, the film thickness difference and/or the temperature difference are calculated based on a target thickness.

Operation 1108 includes adjusting a heat source (such as a laser source) if the film thickness difference and/or the temperature difference exceeds the threshold. The adjustment of the heat source adjusts the film thickness difference and/or the temperature difference to be at or under the threshold. The adjustment can correct a non-uniformity of film deposited on the substrate. In one or more embodiments, the film thickness of operation 1106 is measured in real-time during the flowing of one or more process gases P1 and the heating of the substrate 102 using the heat sources 164A, 164B. In one or more embodiments, the adjustment of operation 1108 is conducted in real-time during the flowing of one or more process gases P1 and the heating of the substrate 102 using the heat sources 164A, 164B.

FIG. 12 is a schematic partial top plan view of the process chamber 101 shown in FIG. 1, according to one or more embodiments.

In FIG. 12, a first temperature sensor 1201 is operable to measure a first temperature at a first radial location in the processing volume 110, and a second temperature sensor 1202 is operable to measure a second temperature at a second radial location in the processing volume. The second radial location is outwardly of the first radial location. A third temperature sensor 1203 is operable to measure a third temperature at a third radial location in the processing volume. The third radial location is outwardly of the second radial location. In one or more embodiments, the heat source 281 is adjusted for correction if a temperature difference between first temperature and the second temperature exceeds a threshold. In one or more embodiments, the second heat source 281 is adjusted for correction if a second temperature difference between the first temperature and the third temperature exceeds a second threshold. In one or more embodiments, the threshold is an average of the temperature difference measured between the first radial location and the second radial location across a rotation of a substrate. In one or more embodiments, the second threshold is an average of the second temperature difference measured between the first radial location and the third radial location across a rotation of a substrate. In the implementation shown in FIG. 12, the ISR(s) are omitted and temperature sensors are used.

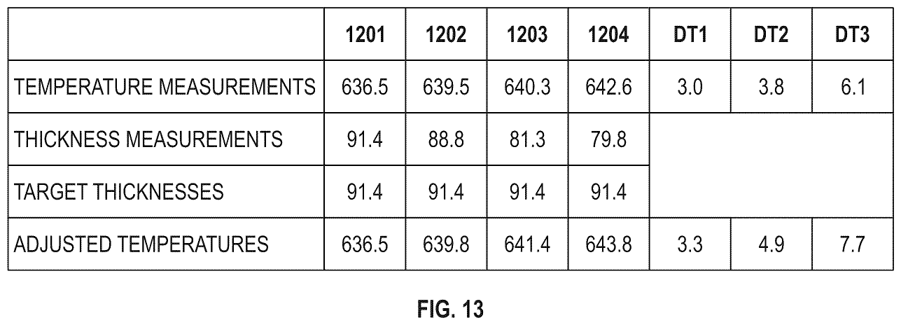

FIG. 13 is a schematic view of a data table, according to one or more embodiments.

According to methods described herein, an initial deposition operation can be conducted and a second row of the table includes temperature measurements (in degrees Celsius) taken by the temperature sensors 1201-1204 in the initial deposition operation. The second row also includes temperature differences DT1-DT3. A first temperature difference DT1 is a difference between a first temperature measurement of the first temperature sensor 1201 and a second temperature measurement of the second temperature sensor 1202. A second temperature difference DT2 is a difference between the first temperature measurement of the first temperature sensor 1201 and a third temperature measurement of the third temperature sensor 1203. A third temperature difference DT3 is a difference between the first temperature measurement of the first temperature sensor 1201 and a fourth temperature measurement of the fourth temperature sensor 1204.

A third row of the table includes thickness measurements (in Angstroms) that are calculated using the temperature measurements of the second row. For example, reference data can be used to calculate the thickness measurements based on the temperature measurements. A fourth row of the table includes target thickness values for regions of the substrate that correspond to the temperature sensors 1201-1204. A fifth row of the table includes adjusted temperatures for the temperature sensors 1201-1204, and adjusted temperature differences for the temperature differences DT1-DT3. The adjusted temperature differences can be used in a second deposition operation as set points for controlling heat sources. For example, the adjusted temperature differences can be used to control the heat source 280, the second heat source 281, sets (such as zones) of the upper heat sources 164A, and/or sets (such as zones) of the lower heat sources 164B.

The present disclosure contemplates that the data, the profile(s), and/or the table(s) described herein can be represented, generated, and/or analyzed in the form of software without visually displaying (such as to a user on a display screen) the signal profile(s) and/or the reference profile(s). The present disclosure also contemplates that the data, the profile(s), and/or the table(s) can optionally be displayed (such as on a display screen to a user). The data, the profile(s), and/or the table(s) can be fed into a feedback control loop (such as of the controller 175) to adjust process recipe(s). The control loop can be closed or open.

Benefits of the present disclosure include enhanced deposition uniformity (which can achieve non-uniformity targets of 1% or less, for example), accurate monitoring and adjustment (e.g., optimizing) of process parameters of process recipes; adjustment of process parameters of process recipes that account for aging and wear of chamber components; and adjustment of process parameters of process recipes in a manner that is real-time and in-situ. Benefits also include reduced or eliminated opening of process chambers and machine down time, enhanced dopant incorporation, higher growth rate, increased yield, and/or higher material (e.g., silicon) concentration.

It is contemplated that one or more aspects disclosed herein may be combined. As an example, one or more aspects, features, components, operations and/or properties of the processing system 100, the process chamber 101, the controller 175, the ISR 285, the second ISR 285b, the third ISR 285c, the heat source 280, the second heat source 281, the process chamber implementation shown in FIG. 5, the process chamber implementation shown in FIG. 6, the adjustment method shown in FIG. 7, the adjustment method shown in FIG. 8, the signal profile of FIG. 9, the signal profile of FIG. 10, the method 1100, the process chamber implementation shown in FIG. 12, and/or the operations and/or data described for FIG. 13 may be combined. Moreover, it is contemplated that one or more aspects disclosed herein may include some or all of the aforementioned benefits.

While the foregoing is directed to examples of the present disclosure, other and further examples of the disclosure may be devised without departing from the basic scope thereof, and the scope thereof is determined by the claims that follow.

What is claimed is:

1. A substrate processing system, comprising:
a chamber body at least partially defining a processing volume;
a substrate support disposed in the processing volume and configured to support a substrate;
one or more gas inlets operable to provide a processing gas that flows horizontally across the processing volume and over the substrate support;
one or more heat sources operable to heat the substrate;
a laser source operable to direct energy to the substrate to provide supplemental heating;
a thickness sensor operable to measure a film thickness on the substrate; and
a controller operable to control the laser source based on the measured film thickness.

2. The substrate processing system of claim 1, wherein the thickness sensor measures the film thickness at a first location on the substrate, and the process chamber further comprises:
a temperature sensor operable to measure a temperature at the first location.

3. The substrate processing system of claim 2, further comprising:
a second thickness sensor operable to measure a second film thickness at a second location on the substrate; and
a second temperature sensor operable to measure a second temperature at the second location.

4. The substrate processing system of claim 1, wherein the thickness sensor is movable to scan across a plurality of locations on the substrate.

5. The substrate processing system of claim 1, wherein the controller is configured to:
determine if a film thickness difference exceeds a threshold; and
adjust one or more of a target location or a power of the laser source if the film thickness difference exceeds the threshold.

6. The substrate processing system of claim 5, wherein the film thickness difference is determined across one or more of:
a plurality of azimuthal locations; or
a time interval.

7. The substrate processing system of claim 5, wherein the film thickness difference is determined across a plurality of radial locations.

8. The substrate processing system of claim 5, wherein the threshold is an average of the film thickness measured across a radial dimension.

9. The substrate processing system of claim 8, wherein the radial dimension extends across an outer diameter of the substrate and through a center of the substrate.

10. The substrate processing system of claim 1, wherein the thickness sensor includes an optical spectrometer, the thickness sensor measures the film thickness while the processing gas flows, and the controller adjusts the laser source in real-time while the processing gas flows.

11. A method of monitoring substrate processing, comprising:
measuring a film thickness in a processing volume of a process chamber;
determining if a film thickness difference of a location in the processing volume exceeds a threshold; and
adjusting a laser source if the film thickness difference exceeds the threshold.

12. The method of claim 11, wherein the film thickness is measured on a substrate.

13. The method of claim 12, wherein the threshold is an average of the film thickness is measured at a substrate location across a rotation of the substrate.

14. The method of claim 12, wherein the threshold is an average of the film thickness is measured across a radial dimension.

15. The method of claim 11, wherein the film thickness difference is determined across a time interval, the laser source corresponding with a first radial location, and the method further comprises:
determining if a second film thickness difference between the first radial location and a second radial location in the processing volume exceeds a second threshold, the second radial location disposed radially outwardly of the first radial location; and
adjusting a second laser source if the second film thickness difference exceeds the second threshold, the second laser source corresponding with the second radial location.

16. A substrate processing system, comprising:
a chamber body at least partially defining a processing volume;
a substrate support disposed in the processing volume;
a first temperature sensor operable to measure a first temperature at a first radial location in the processing volume;
a second temperature sensor operable to measure a second temperature at a second radial location in the processing volume, the second radial location outwardly of the first radial location;
a heat source operable to direct energy into the processing volume; and
a controller configured to:
determine if a temperature difference between the first temperature and the second temperature exceeds a threshold, and
adjust the heat source if the temperature difference exceeds the threshold.

17. The substrate processing system of claim 16, wherein the first radial location corresponds to a central region of a substrate.

18. The substrate processing system of claim 16, further comprising:
a third temperature sensor operable to measure a third temperature at a third radial location in the processing volume, the third radial location outwardly of the second radial location; and
a second heat source operable to direct energy into the processing volume, wherein the controller is configured to:
determine if a second temperature difference between the first temperature and the third temperature exceeds a second threshold, and
adjust the second heat source if the second temperature difference exceeds the second threshold.

19. The substrate processing system of claim 16, wherein the threshold is an average of the temperature difference measured between the first radial location and the second radial location across a rotation of a substrate.

20. The substrate processing system of claim 16, wherein the temperature difference is calculated based on a target thickness.
